(19) United States
(12) Patent Application Publication
(10) Pub. No.: US 2026/0179876 A1
(43) Pub. Date: Jun. 25, 2026

(54) Upwardly-oriented beamline implanter architecture for contactless backside substrate processing

(71) Applicant: Applied Materials, Inc., Santa Clara, CA (US)

(72) Inventors: Taegon Kim, Middleton, MA (US); Soojae Lee, North Andover, MA (US); Joseph C. Olson, Beverly, MA (US); Sage Toko Garrett Doshay, Saratoga, CA (US); Frank Sinclair, Hartland, ME (US)

(21) Appl. No.: 18/987,533

(22) Filed: Dec. 19, 2024

(51) Int. Cl. H01J 37/30; H01J 37/244; H01J 37/317; H01J 49/26

(52) U.S. Cl. CPC H01J 37/3007; H01J 37/244; H01J 37/3171; H01J 49/26

(57) ABSTRACT

A beamline ion implanter is disclosed. The beamline ion implanter generates an upwardly oriented ion beam that is used to impact a workpiece. In some embodiments, a deflector that uses magnets or biased electrodes is used to deflect the ion beam from a substantially horizontal plane to the upward orientation. In other embodiments, the beamline ion implanter is designed so that the ion beam travels substantially within a vertical plane through its entire path from the ion source to the workpiece. The workpiece is mounted on a hollow workpiece holder so that the upwardly oriented ion beam strikes the side of the workpiece that is resting on the workpiece holder.

### FIELD

Embodiments of the present disclosure relate to a beamline implanter architecture that allows processing of the backside without contacting the front surface of the workpiece.

### BACKGROUND

The fabrication of semiconductor devices continues to become more complex. Currently, there are scenarios in which it may be desirable to process both surfaces of a workpiece, such as a silicon, silicon carbide, or GaN wafer. For example, to create certain structures, it may be beneficial to perform an ion implantation process on both surfaces of a workpiece.

One such application of backside (BS) processing is ion implantation to relieve or control wafer stress and physical deformation. Specifically, warpage of the workpiece may occur due to stressed films that are present on the workpiece. This warpage makes lithography more difficult and causes other problems. For example, EUV patterning has a small depth of focus, and workpiece warpage may be sufficient to result in incorrect CDs, poorly reproduced patterned features, and/or defects due to parts of the workpiece being out of focus. Additionally, backside power delivery networks involve also patterning the backside of the workpiece for direct backside source/drain contact, and utilize excellent pattern overlay across the entire workpiece to align the BS metallization to the frontside devices. With significant wafer stress resulting in varying localized warpage across the workpiece, it may not be possible to achieve the desired alignment across the entire workpiece, resulting in decreased yield as misaligned dies will not function as designed. Selective ion implantation into films on the front or back side of the workpiece may be used to reduce wafer curvature.

Typically when both surfaces of the workpiece are to be processed, this may be achieved by processing the front surface first. However, in certain embodiments, the processing of the front surface may include the formation of three-dimensional structures, such as finFETs. Once these three-dimensional structures are created, placing the front surface against an electrostatic chuck risks damaging these structures.

Therefore, it would be beneficial if there were a beamline implanter system that allowed the backside of a workpiece to be processed without having to contact the processed front surface.

### SUMMARY

A beamline ion implanter is disclosed. The beamline ion implanter generates an upwardly oriented ion beam that is used to impact a workpiece. In some embodiments, a deflector that uses magnets or biased electrodes is used to deflect the ion beam from a substantially horizontal plane to the upward orientation. In other embodiments, the beamline ion implanter is designed so that the ion beam travels substantially within a vertical plane through its entire path from the ion source to the workpiece. The workpiece is mounted on a hollow workpiece holder so that the upwardly oriented ion beam strikes the side of the workpiece that is resting on the workpiece holder.

According to one embodiment, a beamline ion implanter system is disclosed. The beamline ion implanter system comprises an ion source to generate ions; a process chamber to receive an ion beam formed from the ions; and a deflector disposed downstream from the ion source in a direction of travel of the ions, the deflector configured to accept the ions travelling along a substantially horizontal path and deflect the ions so that the ions exit the deflector in an upwardly oriented direction and enter the process chamber. In some embodiments, a mass analyzer is used to perform mass analysis on the ions, and the deflector is located downstream from the mass analyzer in a direction of travel of the ions. In certain embodiments, a scanner is located downstream from the mass analyzer to scan the ions back and forth to form the ion beam. In certain embodiments, the deflector is located downstream from the scanner in a direction of travel of the ions. In certain embodiments, the deflector is located upstream from the scanner in a direction of travel of the ions. In certain embodiments, an angle corrector is located downstream from the scanner, and the deflector is located downstream from the angle corrector in a direction of travel of the ions. In certain embodiments, an angle corrector is located downstream from the scanner, and the deflector is located upstream from the angle corrector in a direction of travel of the ions. In some embodiments, a path of the ions after the deflector is between 45° and 90° relative to horizontal. In some embodiments, the deflector comprises one or more magnets. In some embodiments, the deflector comprises a plurality of biased electrodes. In some embodiments, a hollow workpiece holder is disposed in the process chamber, such that a workpiece is supported in an edge exclusion region. In certain embodiments, a scanning motor is used to scan the hollow workpiece holder in a scanning direction. In some embodiments, the ion beam comprises a ribbon ion beam.

According to another embodiment, a beamline ion implanter system is disclosed. The beamline ion implanter system comprises an ion source to generate ions; a mass analyzer; and a process chamber to receive an ion beam formed from the ions; wherein a path of the ions from the ion source to the process chamber is substantially in a vertical plane. In some embodiments, a hollow workpiece holder is disposed in the process chamber, such that a workpiece is supported in an edge exclusion region. In some embodiments, a scanning motor is used to scan the hollow workpiece holder in a scanning direction. In some embodiments, a scanner is located downstream from the mass analyzer in a direction of travel of the ions to scan the ions back and forth to form the ion beam. In some embodiments, the ion beam comprises a ribbon ion beam. In some embodiments, the path of the ions entering the process chamber is between 45° and 90° relative to horizontal.

### BRIEF DESCRIPTION OF THE FIGURES

For a better understanding of the present disclosure, reference is made to the accompanying drawings, which are incorporated herein by reference and in which:

FIG. 1 is a beamline ion implanter that generates an upwardly oriented ion beam according to one embodiment;

FIGS. 2A-2B show a front and side view of the process chamber, respectively, according to one embodiment;

FIGS. 2C-2D show side views of the process chamber according to two additional embodiments;

FIG. 3 is a beamline ion implanter that generates an upwardly oriented ion beam according to a second embodiment;

FIG. 4 is a beamline ion implanter that generates an upwardly oriented ion beam according to a third embodiment; and

FIG. 5 shows a cross section of the deflector according to one embodiment.

### DETAILED DESCRIPTION

As described above, in certain systems, it may be desirable to process the backside of a workpiece without contacting the useable region of the front surface.

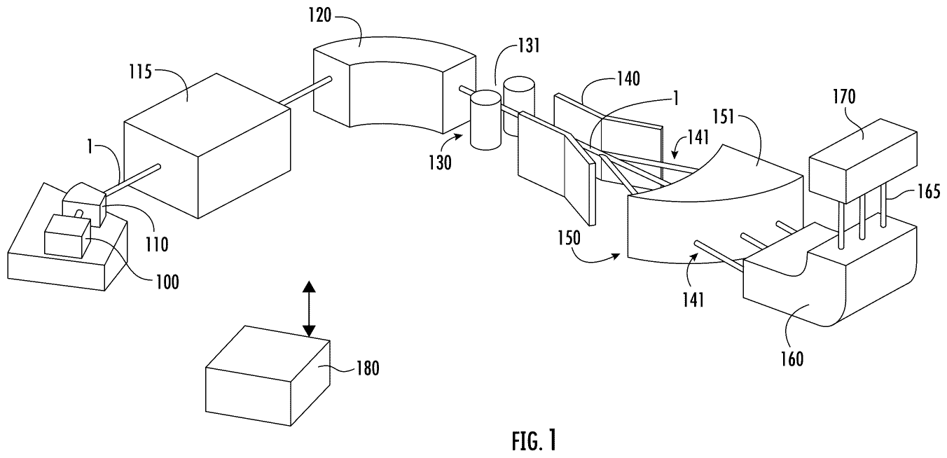

FIG. 1 shows a beamline ion implanter system that may be used to create an upwardly oriented ion beam that enters a process chamber according to one embodiment.

The beamline ion implanter system includes an ion source 100 comprising a plurality of chamber walls defining an ion source chamber. In certain embodiments, the ion source 100 may be an RF ion source. In this embodiment, an RF antenna may be disposed against a dielectric window. This dielectric window may comprise part or all of one of the chamber walls. The RF antenna may comprise an electrically conductive material, such as copper. An RF power supply is in electrical communication with the RF antenna. The RF power supply may supply an RF voltage to the RF antenna. The power supplied by the RF power supply may be between 0.1 and 10 kW and may be any suitable frequency, such as between 1 and 100 MHz. Further, the power supplied by the RF power supply may be pulsed.

In another embodiment, a cathode is disposed within the ion source chamber. A filament is disposed behind the cathode and energized so as to emit electrons. These electrons are attracted to the cathode, which in turn emits electrons into the ion source chamber. This cathode may be referred to as an indirectly heated cathode (IHC), since the cathode is heated indirectly by the electrons emitted from the filament.

Other embodiments are also possible. For example, the plasma may be generated in a different manner, such as by a Bernas ion source, a capacitively coupled plasma (CCP) source, or a microwave or ECR (electron-cyclotron-resonance) ion source. The manner in which the plasma is generated is not limited by this disclosure.

One chamber wall, referred to as the extraction plate, includes an extraction aperture. The extraction aperture may be an opening through which the ions 1 generated in the ion source chamber are extracted and directed toward a workpiece. The extraction aperture may be any suitable shape. In certain embodiments, the extraction aperture may be round or oval.

Disposed outside and proximate the extraction aperture of the ion source 100 are extraction optics 110. In certain embodiments, the extraction optics 110 comprises one or more electrodes. Each electrode may be a single electrically conductive component with an aperture disposed therein. Alternatively, each electrode may be comprised of two electrically conductive components that are spaced apart so as to create the aperture between the two components. The electrodes may be a metal, such as tungsten, molybdenum or titanium. The electrodes may alternatively be made out of graphite. One or more of the electrodes may be electrically connected to ground. In certain embodiments, one or more of the electrodes may be biased using an electrode power supply. The electrode power supply may be used to bias one or more of the electrodes relative to the ion source so as to attract ions through the extraction aperture. The extraction aperture and the aperture in the extraction optics are aligned such that the ions 1 pass through both apertures.

Located downstream from the extraction optics 110 are one or more beam line components. The beam line components guide the ions from the ion source 100 toward the workpiece. In some embodiments, a mass analyzer 120 is located downstream from the extraction optics 110. An acceleration/deceleration column 115 may be positioned between the extraction optics 110 and mass analyzer 120. The mass analyzer 120 uses magnetic fields to guide the path of the extracted ions 1. The magnetic fields affect the flight path of ions according to their mass and charge. A mass resolving device 130 that has a resolving aperture 131 is disposed at the output, or distal end, of the mass analyzer 120. By proper selection of the magnetic fields, only those ions 1 that have a selected mass and charge will be directed through the resolving aperture 131. Other ions will strike the mass resolving device 130 or a wall of the mass analyzer 120 and will not travel any further in the system. The ions that pass through the mass resolving device 130 may form a spot beam.

The spot beam may then enter a scanner 140 which is disposed downstream from the mass resolving device 130. The scanner 140 causes the spot beam to be fanned out into a plurality of divergent beamlets, referred to as a scanned ion beam. This scanned ion beam 141 is much larger in one dimension, referred to as the width, than in the second, orthogonal dimension, referred to as height. The scanner 140 may be electrostatic or magnetic. The scanner 140 may comprise spaced-apart scan plates connected to a scan generator. The scan generator applies a scan voltage waveform, such as a sawtooth waveform, for scanning the ion beam in accordance with the electric field between the scan plates. The scanned direction of the ion beam is referred to as its width throughout this disclosure.

Angle corrector 150 is designed to deflect ions in the scanned ion beam 141 to produce a scanned ion beam having parallel ion trajectories, thus focusing the scanned ion beam. Specifically, the angle corrector 150 is used to alter the diverging ion trajectory paths into substantially parallel paths of a scanned ion beam. In particular, angle corrector 150 may comprise magnetic pole pieces 151 which are spaced apart to define a gap and a magnet coil (not shown) which is coupled to a power supply. The scanned ion beam 141 passes through the gap between the magnetic pole pieces 151 and is deflected in accordance with the magnetic field in the gap. The magnetic field may be adjusted by varying the current through the magnet coil. Beam scanning and beam focusing are performed in a selected plane, such as a horizontal plane.

In certain embodiments, the path of ions 1 from the ion source 100 to the angle corrector 150 is substantially in the horizontal plane. In this disclosure, the term “substantially horizontal” denotes that the height of the ions 1 exiting the ion source 100 is within half a meter of the height of the scanned ion beam exiting the angle corrector 150.

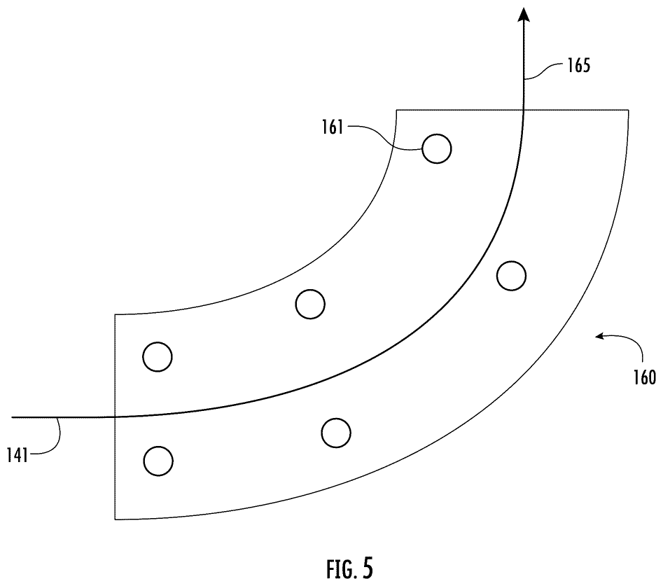

In this embodiment, a deflector 160 is located downstream from the angle corrector 150. The deflector 160 serves to change the trajectory of the scanned ion beam 141 from substantially horizontal to an angle of between 45° and 90° (relative to horizontal). In other words, the width dimension of the scanned ion beam 141 may be substantially horizontal when entering the deflector 160. The deflector 160 may be made using magnets which deflect the trajectory of the ions upward. In another embodiment, a cross section of which is shown in FIG. 5, the deflector 160 may be made using a plurality of biased rod-like electrodes 161 which deflect the trajectory of the ions upward. This upwardly oriented ion beam 165 then enters the process chamber 170. In certain embodiments, this upwardly oriented ion beam 165 may be vertical.

A controller 180 may be in communication with one or more of the components in the beamline ion implanter so as to receive information from these components or send control signals to these components. The controller 180 may include a processing unit, such as a microcontroller, a personal computer, a special purpose controller, or another suitable processing unit. The controller 180 may also include a non-transitory storage element, such as a semiconductor memory, a magnetic memory, or another suitable memory. This non-transitory storage element may contain instructions and other data that allows the controller 180 to perform the functions described herein.

While FIG. 1 describes a beamline ion implanter that creates a scanned ion beam, other embodiments are also possible. For example, the system may be modified to have an ion source with an elongated slot such that a ribbon ion beam is extracted and travels through the system. Since the ion beam is already a ribbon ion beam, in this embodiment, the scanner 140 is omitted and the angle corrector 150 may be replaced with a collimator and/or an acceleration/deceleration stage. The deflector 160 may be located at any point after the mass resolving device 130 in this embodiment.

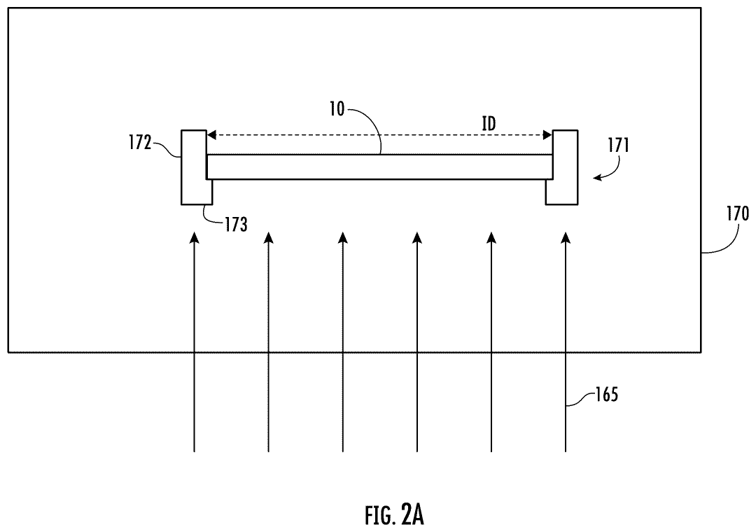

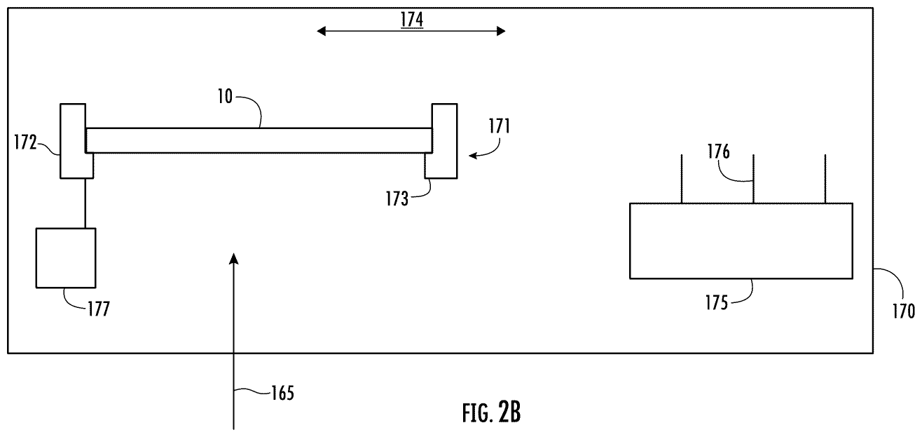

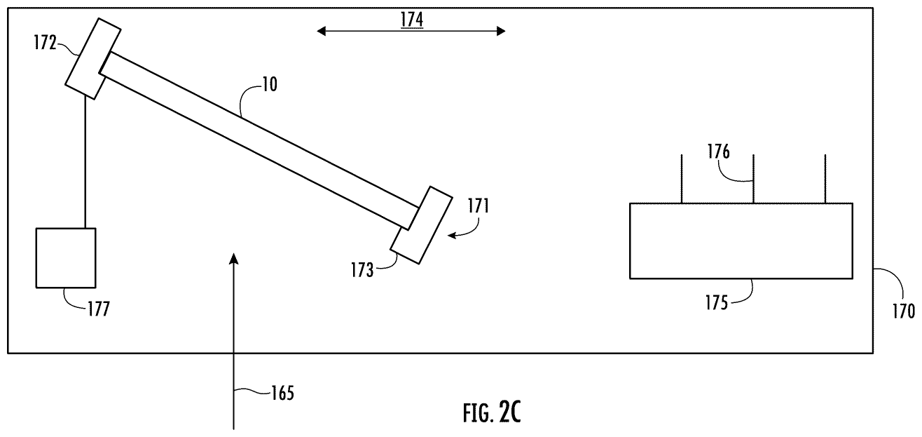

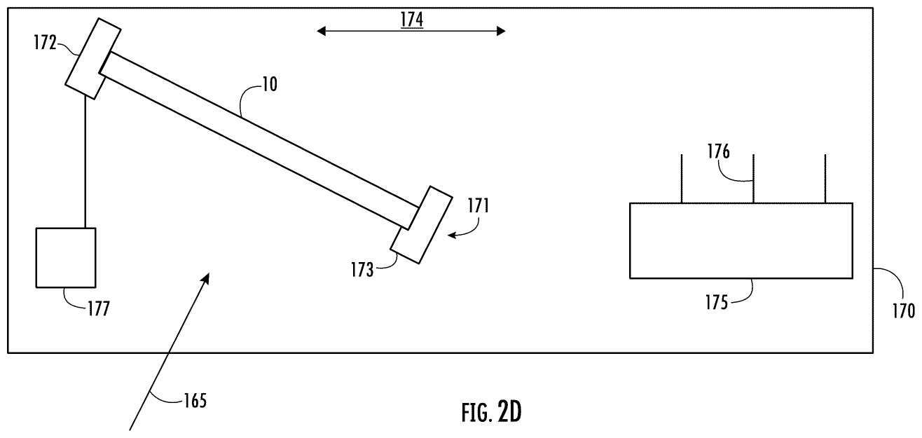

FIGS. 2A-2B show one embodiment of the process chamber 170 in more detail. FIG. 2A is a front view, while FIG. 2B is a side view. The process chamber 170 receives the upwardly oriented ion beam 165, which impacts the backside of a workpiece 10, which is disposed on a hollow workpiece holder 171. As noted above, this may be a scanned ion beam or a ribbon ion beam.

The hollow workpiece holder 171 may include sidewalls 172 that have an inner diameter (ID) that is slightly larger than the diameter of the workpiece 10. Extending radially inward from the bottom of the sidewalls 172 is a support shelf 173. The support shelf 173 may extend inward a distance of between 2 and 5 mm, which corresponds to the width of the edge exclusion region of the workpiece 10. In this way, the support shelf 173 does not contact any part of the workpiece 10 that may contain usable devices or structures. Of course, the hollow workpiece holder 171 may be formed differently. However, in all embodiments, there is no bottom surface of the workpiece holder 171 so that the upwardly oriented ion beam 165 may contact the entirety of the workpiece facing the ion beam (except the edge exclusion region) without interference or blockage.

As shown in FIG. 2A, the upwardly oriented ion beam 165 has a width that is at least equal to the diameter of the workpiece 10. To implant the entirety of the surface of the workpiece facing the upwardly oriented ion beam 165, the hollow workpiece holder 171 moves in a scanning direction 174 that is perpendicular to the width of the upwardly oriented ion beam 165 (see FIG. 2B). A scanning motor 177 is used to translate the hollow workpiece holder 171 in the horizontal direction.

FIG. 2B shows the process chamber 170 from a side view. In this figure, the width of the upwardly oriented ion beam 165 is perpendicular to the plane of the page. Further, the process chamber 170 may include a transfer station 175 that includes lift pins 176. To remove a workpiece from the hollow workpiece holder 171, the hollow workpiece holder 171 moves along scanning direction 174 so as to be above transfer station 175. This may be referred to as the loading position. Lift pins 176 are then actuated and extend a height that is above the hollow workpiece holder 171, lifting the processed workpiece above the hollow workpiece holder 171. Then, a robotic end effector (not shown) may be used to remove the workpiece 10 from the lift pins 176. The robotic end effector may then place an unprocessed workpiece on the lift pins 176. Once placed, the lift pins 176 may be lowered, allowing the workpiece to rest on the support shelf 173 of the hollow workpiece holder 171. The hollow workpiece holder 171 may then move along scanning direction 174 back to a processing position.

While FIGS. 2A-2B show the hollow workpiece holder 171 as being horizontal, it is understood that the hollow workpiece holder 171 may be oriented at any angle that allows gravity to retain the workpiece 10 on the hollow workpiece holder 171. For example, the hollow workpiece holder 171 may be tilted by up to 45° relative to the horizon. An example of this configuration is shown in FIG. 2C.

Further, as noted above, the deflector 160 serves to change the trajectory of the scanned ion beam 141 from substantially horizontal to an angle of between 45° and 90°. FIGS. 2A-2C show the upwardly oriented ion beam 165 as being vertical. FIG. 2D shows another embodiment. In this embodiment, the deflector 160 changes the trajectory of the upwardly oriented ion beam 165 by less than 90°. In this embodiment, the workpiece holder 171 is also tilted so that the upwardly oriented ion beam 165 strikes the workpiece 10 in a perpendicular direction. In this embodiment, the scanning direction 174 may be horizontal or may be along the tilted direction.

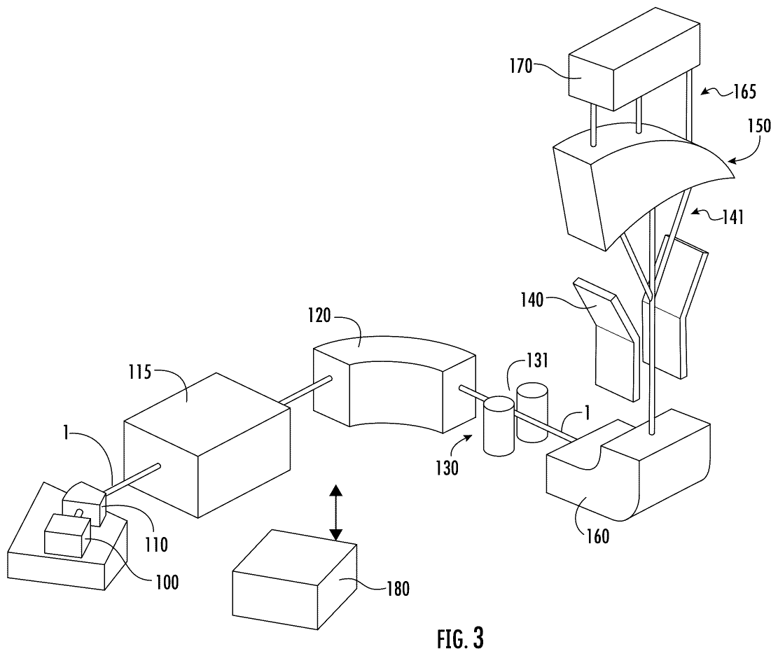

FIG. 3 shows a second embodiment of a beamline ion implanter system that generates an upwardly oriented ion beam. In this embodiment, the deflector 160 is moved upstream so as to be immediately after the mass resolving device 130. In this way, the deflector 160 is deflecting a spot beam rather than a scanned ion beam. This may simplify the design of the deflector 160. Thus, in this embodiment, the path from the ion source 100 to the mass resolving device 130 is substantially horizontal, and the path of the ions and the components after the deflector 160 are oriented upwardly.

Note that the deflector 160 may also be disposed after the scanner 140 but before the angle corrector 150, if desired. Thus, in all of these embodiments, the path from the ion source 100 to at least the mass resolving device 130 is substantially horizontal. The deflector 160 is positioned after the mass resolving device 130 to orient the ion beam upward. All of the components in the beamline after the deflector 160 are also oriented upwardly.

Note that the implanter of FIG. 3 may also be modified to utilize an ion source that generates a ribbon ion beam. In this embodiment, the scanner 140 is omitted and the angle corrector 150 may be replaced with a collimator and/or an acceleration/deceleration stage. The deflector 160 may be located at any point after the mass resolving device 130 in this embodiment.

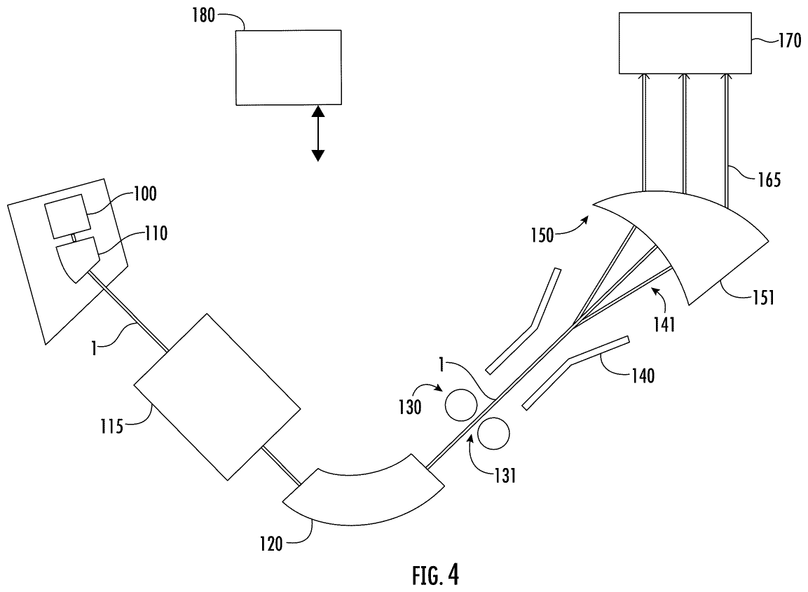

In another embodiment, shown in FIG. 4, the entire beamline implanter is rotated 90° so that the path of the ions throughout the beamline are substantially within a vertical plane. In other words, the center of the ion path may deviate from this vertical plane by less than 1 foot throughout its length. In other words, FIG. 4 represents a side view of the beamline ion implanter, wherein the mass analyzer 120 is the closest component to the floor. Such a beamline system may result in a process chamber that is roughly 2 meters above the level of the floor. The process chamber 170 may be as described in FIGS. 2A-2B.

Again, note that the implanter of FIG. 4 may also be modified to utilize an ion source that generates a ribbon ion beam. In this embodiment, the scanner 140 is omitted and the angle corrector 150 may be replaced with a collimator and/or an acceleration/deceleration stage.

Note that while the systems are described with respect to processing the backside of a workpiece, these systems may also be used to process the front side as well.

The systems described herein have many advantages. These beamline ion implanter systems allow processing of either side of the workpiece 10, without contacting the useable area on the workpiece. This allows the front surface of the workpiece to be processed, and then subsequent processing of the back surface without risking damage to the nanostructures formed on the front surface.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A beamline ion implanter system, comprising:
an ion source to generate ions;
a process chamber to receive an ion beam formed from the ions; and
a deflector disposed downstream from the ion source in a direction of travel of the ions, the deflector configured to accept the ions travelling along a substantially horizontal path and deflect the ions so that the ions exit the deflector in an upwardly oriented direction and enter the process chamber.

2. The beamline ion implanter system of claim 1, further comprising a mass analyzer to perform mass analysis on the ions, wherein the deflector is located downstream from the mass analyzer in a direction of travel of the ions.

3. The beamline ion implanter system of claim 2, further comprising a scanner located downstream from the mass analyzer to scan the ions back and forth to form the ion beam.

4. The beamline ion implanter system of claim 3, wherein the deflector is located downstream from the scanner in a direction of travel of the ions.

5. The beamline ion implanter system of claim 3, wherein the deflector is located upstream from the scanner in a direction of travel of the ions.

6. The beamline ion implanter system of claim 3, further comprising an angle corrector located downstream from the scanner, wherein the deflector is located downstream from the angle corrector in a direction of travel of the ions.

7. The beamline ion implanter system of claim 3, further comprising an angle corrector located downstream from the scanner, wherein the deflector is located upstream from the angle corrector in a direction of travel of the ions.

8. The beamline ion implanter system of claim 1, wherein a path of the ions after the deflector is between 45° and 90° relative to horizontal.

9. The beamline ion implanter system of claim 1, wherein the deflector comprises one or more magnets.

10. The beamline ion implanter system of claim 1, wherein the deflector comprises a plurality of biased electrodes.

11. The beamline ion implanter system of claim 1, further comprising a hollow workpiece holder in the process chamber, such that a workpiece is supported in an edge exclusion region.

12. The beamline ion implanter system of claim 11, further comprising a scanning motor to scan the hollow workpiece holder in a scanning direction.

13. The beamline ion implanter system of claim 1, wherein the ion beam comprises a ribbon ion beam.

14. A beamline ion implanter system, comprising:
an ion source to generate ions;
a mass analyzer; and
a process chamber to receive an ion beam formed from the ions;
wherein a path of the ions from the ion source to the process chamber is substantially in a vertical plane.

15. The beamline ion implanter system of claim 14, further comprising a hollow workpiece holder in the process chamber, such that a workpiece is supported in an edge exclusion region.

16. The beamline ion implanter system of claim 15, further comprising a scanning motor to scan the hollow workpiece holder in a scanning direction.

17. The beamline ion implanter system of claim 14, further comprising a scanner located downstream from the mass analyzer in a direction of travel of the ions to scan the ions back and forth to form the ion beam.

18. The beamline ion implanter system of claim 14, wherein the ion beam comprises a ribbon ion beam.

19. The beamline ion implanter system of claim 14, wherein the path of the ions entering the process chamber is between 45° and 90° relative to horizontal.
